(19) United States
(12) Patent Application Publication
(10) Pub. No.: US 2026/0077392 A1
(43) Pub. Date: Mar. 19, 2026

(54) MASK CLEANING DEVICE AND METHOD OF CLEANING MASK USING THE SAME

(71) Applicant: Samsung Display Co., LTD., Yongin-si (KR)

(72) Inventors: SEUNGGUN LEE, Yongin-si (KR); YONG-WOO LEE, Yongin-si (KR); JAIHYUK CHOI, Yongin-si (KR)

(21) Appl. No.: 19/200,036

(22) Filed: May 6, 2025

(30) Foreign Application Priority Data
Sep. 19, 2024 (KR) 10-2024-0126353

(51) Int. Cl. B08B 3/12; B08B 13/00; G03F 1/82; G03F 7/00

(52) U.S. Cl. CPC B08B 3/12; B08B 13/00; G03F 1/82; G03F 7/70925

(57) ABSTRACT

A mask cleaning device includes a bath part including an upper bath and a lower bath spaced apart from the upper bath, where the bath part allows the mask to be placed between the upper bath and the lower bath, a cleaning solution supply part connected to the bath part to supply a cleaning solution to the bath part, an ultrasonic application part disposed in the bath part to generate an ultrasonic vibration, and a cleaning solution recovery part connected to the bath part to recover the cleaning solution.

This application claims priority to Korean Patent Application No. 10-2024-0126353, filed on Sep. 19, 2024, and all the benefits accruing therefrom under 35 U.S.C. § 119, the content of which in its entirety is herein incorporated by reference.

### BACKGROUND

### 1. Field

The present disclosure relates to a mask cleaning device and a method of cleaning the mask using the mask cleaning device.

### 2. Description of Related Art

A light emitting display device typically includes pixels and a light emitting element disposed in each pixel. The light emitting element may include two electrodes and a light emitting layer disposed between the two electrodes. The light emitting layers disposed in the pixels are divided into multiple groups.

In a manufacturing process of a light emitting device, masks may be used to deposit the multiple groups of light emitting layers on a work substrate. Patterned light emitting layers are formed by placing the work substrate above the mask and depositing a light emitting material onto the work substrate.

### SUMMARY

In a manufacturing process of a light emitting device using a mask, after a deposition process is finished, the mask used in the deposition process may contain foreign substances. Accordingly, operators may directly remove foreign substances from the masks during a cleaning process. However, due to human error occurring during the cleaning process, foreign substances may remain on the mask even after performing the cleaning process, such that the cleaning uniformity may be reduced.

In addition, since the cleaning process is performed over the entire area of the mask, processes may be undesirably carried out in a tension area, which affects a deposition area of the mask. As a result, the tension area is damaged and separated. When the deposition process of the display device is performed using the damaged mask, defective light emitting layers may be formed.

The present disclosure provides a mask cleaning device capable of improving a cleaning quality and reducing damages of a mask.

The present disclosure provides a method of cleaning the mask, which is capable of improving a cleaning quality and reducing damages of the mask using the mask cleaning device.

Embodiments of the invention provide a mask cleaning device including a bath part including an upper bath and a lower bath spaced apart from the upper bath, where the bath part allows the mask to be placed between the upper bath and the lower bath, a cleaning solution supply part connected to the bath part to supply a cleaning solution to the bath part, an ultrasonic application part disposed in the bath part to generate an ultrasonic vibration, and a cleaning solution recovery part connected to the bath part to recover the cleaning solution.

In an embodiment, the mask may include a first portion having a mesh shape, a second portion surrounding the first portion and tensioning the first portion, and a frame portion surrounding the second portion.

In an embodiment, the first portion may have a thickness in a range of about 50 micrometers to about 60 micrometers.

In an embodiment, when the mask may be disposed between the upper bath and the lower bath, the first portion is disposed between the upper bath and the lower bath.

In an embodiment, the mask cleaning device may further include a first pillar which is disposed under the frame portion and supports the frame portion, a fixing clamp fixing the frame portion thereto, and a second pillar which is connected to the fixing clamp and supports the fixing clamp.

In an embodiment, the mask cleaning device may further include a moving part which is disposed on the upper bath and moves the upper bath, a motor which provides a driving force to the moving part, and a rail connected to the second pillar, where the moving part moves along the rail.

In an embodiment, the cleaning solution supply part may include a cleaning solution supply tank which supplies the cleaning solution to the upper bath, a first pipe connected between the upper bath and the cleaning solution supply tank, and a cleaning solution supply nozzle disposed in the upper bath and connected to the first pipe.

In an embodiment, the cleaning solution supply part may further include a pump which controls a supply of the cleaning solution to the upper bath from the cleaning solution supply tank.

In an embodiment, the mask cleaning device may further include a first level sensor disposed outside the upper bath to detect a first water level of the cleaning solution contained in the upper bath.

In an embodiment, when the first water level of the cleaning solution contained in the upper bath, which is detected by the first level sensor, exceeds a reference upper water level of the cleaning solution, the pump may stop the supply of the cleaning solution to the upper bath.

In an embodiment, after the pump stops the supply of the cleaning solution to the upper bath, the ultrasonic application part may generate the ultrasonic vibration to clean the first portion.

In an embodiment, the ultrasonic vibration may have a frequency range from about 35 kilohertz kHz)) to about 172 kHz.

In an embodiment, the cleaning solution recovery part may include a cleaning solution recovery tank which recovers the cleaning solution from the lower bath and a second pipe connected between the lower bath and the cleaning solution recovery tank.

In an embodiment, the cleaning solution recovery part may further include a valve which controls a recovery of the cleaning solution to the cleaning solution recovery tank from the lower bath.

In an embodiment, the mask cleaning device may further include a second level sensor disposed outside the lower bath to detect a second water level of the cleaning solution contained in the lower bath.

In an embodiment, when the second water level of the cleaning solution contained in the lower bath, which is detected by the second level sensor, is below a reference lower water level of the cleaning solution, the valve may be closed to stop the recovery of the cleaning solution to the cleaning solution recovery tank from the lower bath.

Embodiments of the invention provide a mask cleaning method including fixing a mask to a fixing clamp to place the mask on a lower bath, placing an upper bath on the mask to overlap the lower bath to allow the upper bath and the lower bath to form a sealed space therebetween, supplying a cleaning solution into the sealed spaced between the upper and lower baths, performing an ultrasonic cleaning on the mask, recovering the cleaning solution used in the ultrasonic cleaning of the mask, and moving the upper bath to separate the upper bath from the lower bath.

In an embodiment, the placing of the mask on the lower bath to overlap the lower bath may include placing a first portion between the upper bath and the lower bath.

In an embodiment, the supplying the cleaning solution may include operating a pump connected between the upper bath and a cleaning solution supply tank to supply the cleaning solution contained in the cleaning solution supply tank to the upper bath.

In an embodiment, the supplying the cleaning solution may further include allowing a first level sensor disposed outside the upper bath to detect a first water level of the cleaning solution contained in the upper bath.

In an embodiment, the supplying the cleaning solution may further include stopping the pump when the first level sensor detects that the first water level of the cleaning solution contained in the upper bath exceeds a reference upper water level of the cleaning solution.

In an embodiment, the recovering the cleaning solution may include opening a valve connected to the lower bath and a cleaning solution recovery tank to recover the cleaning solution contained in the lower bath to the cleaning solution recovery tank.

In an embodiment, the recovering the cleaning solution may further include allowing a second level sensor disposed outside the lower bath to detect a second water level of the cleaning solution contained in the lower bath.

In an embodiment, the recovering the cleaning solution may include closing the value when the second level sensor detects that the second water level of the cleaning solution contained in the lower bath is below a reference lower water level of the cleaning solution.

In an embodiment, the performing the ultrasonic cleaning on the mask may include generating an ultrasonic vibration using an ultrasonic application part disposed in the lower bath to clean the first portion.

Embodiments of the invention provide a mask cleaning method including providing a mask including a first portion having a mesh shape, a second portion surrounding the first portion, and a frame portion surrounding the second portion, wiping the mask with a cleaning solution, placing the mask between an upper bath and a lower bath to clean the mask using an ultrasonic vibration, immersing the cleaned mask using the ultrasonic vibration into a deionized water, and drying the immersed mask. The cleaning of the mask using the ultrasonic vibration includes placing the mask on the lower bath to fix the mask to a fixing clamp, placing the upper bath on the mask to allow the upper bath and the lower bath to form a sealed structure, supplying the cleaning solution into the upper and lower baths that are sealed, ultrasonic cleaning the mask, recovering the cleaning solution used in the ultrasonic cleaning of the mask, and moving the upper bath to separate the upper bath from the lower bath.

According to embodiments of the mask cleaning device and the mask cleaning method, only a deposition area of the mask is cleaned using the ultrasonic vibration, and thus, damages to the mask are minimized while providing high cleaning efficiency.

### BRIEF DESCRIPTION OF THE DRAWINGS

FIG. 1A is a view illustrating a mask according to an embodiment of the present disclosure;

FIG. 1B is a cross-sectional view illustrating the mask taken along line I-I′ of FIG. 1A;

FIG. 2 is a view illustrating a mask cleaning device according to an embodiment of the present disclosure;

FIG. 3 is a view illustrating a detailed structure of a part A of FIG. 2;

FIG. 4 is a flowchart illustrating a method of cleaning a mask according to an embodiment of the present disclosure;

FIG. 5 is a flowchart illustrating an embodiment of an ultrasonic cleaning process shown in FIG. 4; and

FIGS. 6A to 6F are views illustrating an embodiment of an operation of a mask cleaning device.

### DETAILED DESCRIPTION

The invention now will be described more fully hereinafter with reference to the accompanying drawings, in which various embodiments are shown. This invention may, however, be embodied in many different forms, and should not be construed as limited to the embodiments set forth herein. Rather, these embodiments are provided so that this disclosure will be thorough and complete, and will fully convey the scope of the invention to those skilled in the art.

It will be understood that when an element is referred to as being “on” another element, it can be directly on the other element or intervening elements may be present therebetween. In contrast, when an element is referred to as being “directly on” another element, there are no intervening elements present. In the present disclosure, it will be understood that when an element (or area, layer, or portion) is referred to as being “connected to” or “coupled to” another element or layer, it can be directly connected or coupled to the other element or layer or intervening elements or layers may be present.

Like numerals refer to like elements throughout. In the drawings, the thickness, ratio, and dimension of components are exaggerated for effective description of the technical content.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

Furthermore, relative terms, such as “lower” or “bottom” and “upper” or “top,” may be used herein to describe one element's relationship to another element as illustrated in the Figures. It will be understood that relative terms are intended to encompass different orientations of the device in addition to the orientation depicted in the Figures. For example, if the device in one of the figures is turned over, elements described as being on the “lower” side of other elements would then be oriented on “upper” sides of the other elements. The term “lower,” can therefore, encompasses both an orientation of “lower” and “upper,” depending on the particular orientation of the figure. Similarly, if the device in one of the figures is turned over, elements described as “below” or “beneath” other elements would then be oriented “above” the other elements. The terms “below” or “beneath”can, therefore, encompass both an orientation of above and below.

Unless otherwise defined, all terms including technical and scientific terms used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. Thus, reference to “an” element in a claim followed by reference to “the” element is inclusive of one element and a plurality of the elements. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the figures are schematic in nature and their shapes are not intended to illustrate the precise shape of a region and are not intended to limit the scope of the present claims.

Hereinafter, embodiments of the present disclosure will be described with reference to the accompanying drawings.

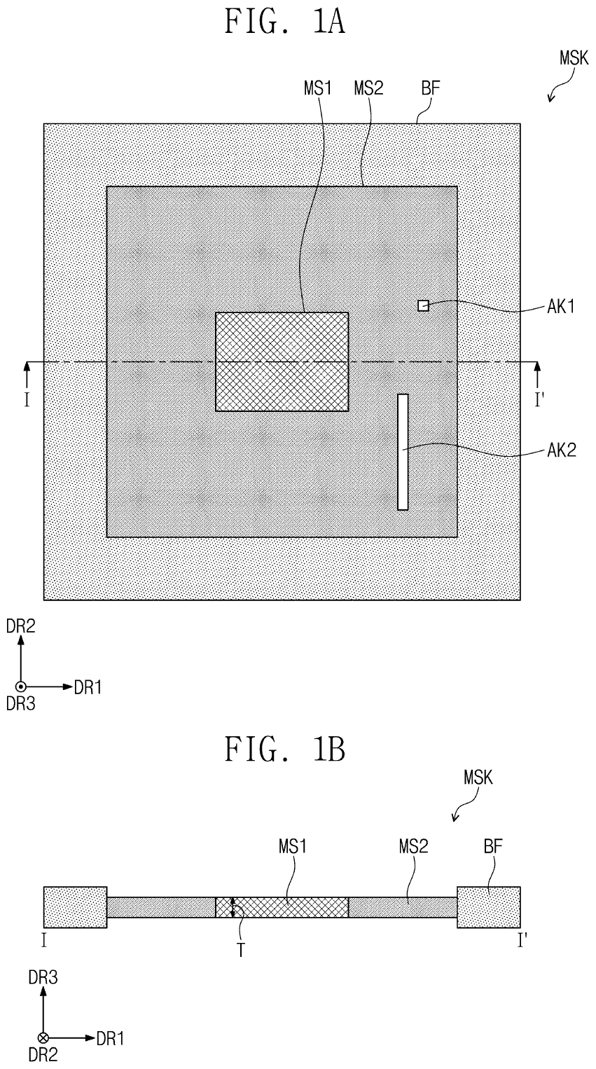

FIG. 1A is a view illustrating a mask MSK according to an embodiment of the present disclosure, and FIG. 1B is a cross-sectional view illustrating the mask MSK taken along line I-I′ of FIG. 1A.

Referring to FIG. 1A, an embodiment of the mask MSK may have a surface on a plane defined by a first direction DR2 and a second direction DR2 intersecting the first direction DR1. Hereinafter, a direction substantially perpendicular to the plane defined by the first direction DR1 and the second direction DR2 may be referred to as a third direction DR3. The third direction DR3 may be a thickness direction of the mask MSK. In the present disclosure, the expression “when viewed in a plane” or “in a plan view” may mean a state of being viewed in the third direction DR3.

The mask MSK may include a first portion MS1, a second portion MS2, and a frame portion BF.

The first portion MS1 may have a rectangular shape defined by long sides extending in the first direction DR1 and short sides extending in the second direction DR2 in a plan view. The first portion MS1 may include sticks extending in a diagonal direction and connected to each other. The sticks may be connected to each other to define a plurality of holes. In an embodiment, for example, the first portion MS1 may have a mesh shape. The sticks may be arranged in a grid-like pattern. The first portion MS1 may be a deposition area.

The first portion MS1 may include a metal material. In an embodiment, for example, the first portion MS1 may include stainless steel (SUS).

The second portion MS2 may surround the first portion MS1. The second portion MS2 may tension the first portion MS1, i.e., tighten the first portion MS1 to a desired or appropriate degree. The second portion MS2 may effectively prevent the first portion MS1 from sagging. In an embodiment, for example, the second portion MS2 may include a polymer material with high resistance to temperature changes and high tensile strength. The second portion MS2 may be a tension area.

When a mask process and a cleaning process are repeatedly performed, the first portion MS1 may be deformed and may sag downward. The first portion MS1, which sags downward, may be pulled by the second portion MS2, such that the first portion MS1 may form a uniform grid-like pattern without being deformed.

The second portion MS2 may include first and second alignment keys AK1 and AK2. The first and second alignment keys AK1 and AK2 may include a photo alignment key, a wafer alignment key, an overlay key, or the like. The first and second alignment keys AK1 and AK2 may provide location information of the mask MSK. In an embodiment, for example, the first and second alignment keys AK1 and AK2 may be formed from a metal material that is less susceptible to deformation under temperature changes. In an embodiment, as shown in FIG. 1A, the first and second alignment keys AK1 and AK2 may have square and bar shapes, respectively, however, the present disclosure should not be limited thereto or thereby.

The frame portion BF may surround the second portion MS2. The frame portion BF may include a metal material. The frame portion BF may include stainless steel (SUS). The frame portion BF may be tapped after being bonded to an edge portion of the second portion MS2. The frame portion BF may overlap the edge portion of the second portion MS2 in the third direction DR3. In an embodiment, for example, the frame portion BF may overlap the edge portion of the second portion MS2 and may hold the second portion MS2, which applies tension to the first portion MS1, to effectively prevent deformation of the second portion MS2.

Referring to FIG. 1B, in an embodiment, the frame portion BF may have a thickness greater than the first and second portions MS1 and MS2. In an embodiment, for example, the first portion MS1 may have a thickness T in a range of about 50 micrometers to about 60 micrometers. The frame portion BF may be provided with a separate coupling member or fixing member.

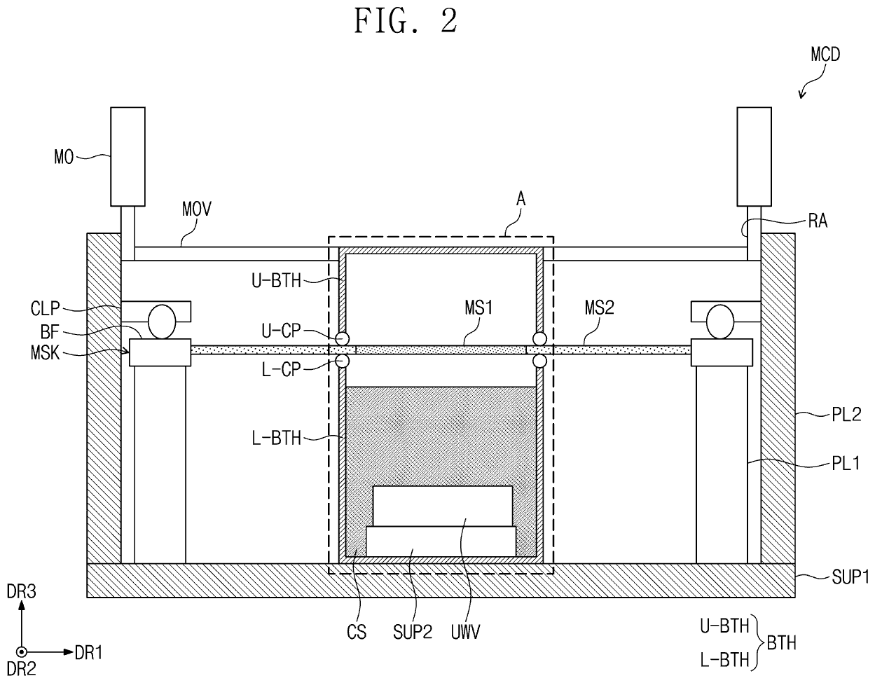

FIG. 2 is a view illustrating a mask cleaning device MCD according to an embodiment of the present disclosure.

Referring to FIG. 2, an embodiment of the mask cleaning device MCD may include first and second supporters SUP1 and SUP2, a plurality of first and second pillars PL1 and PL2, a plurality of fixing clamps CLP, a moving part MOV, a plurality of rails RA, a plurality of motors MO, an upper bath U-BTH, a lower bath L-BTH, and an ultrasonic application part UWV.

The first supporter SUP1 may have a surface (or be) on a plane defined by the first direction DR1 and the second direction DR2 intersecting the first direction DR1.

The first and second pillars PL1 and PL2 may be disposed on the first supporter SUP1. The first pillars PL1 may be spaced apart from each other in the first direction DR1, and each of the first pillars PL1 may extend in the third direction DR3. The second pillars PL2 may be spaced apart from each other in the first direction DR1, and each of the second pillars PL2 may extend in the third direction DR3, which may be a thickness direction of the first support SUP1. The first pillars PL1 may be positioned more closer to a center of the first supporter SUP1 than the second pillars PL2 is. In an embodiment, the second pillars PL2 may surround the first pillars PL1 in a plan view or when viewed in the third direction DR3.

A bath part BTH may be disposed on the first supporter SUP1. The bath part BTH may include the upper bath U-BTH and the lower bath L-BTH. The upper bath U-BTH and the lower bath L-BTH may extend in the third direction DR3 to define an inner space. During the cleaning process, a cleaning solution CS may be contained in the inner space of each of the upper bath U-BTH and the lower bath L-BTH. The upper bath U-BTH may be spaced apart from the lower bath L-BTH in the third direction DR3.

The lower bath L-BTH may be disposed on the first supporter SUP1. The second supporter SUP2 may be disposed in the lower bath L-BTH. The ultrasonic application part UWV may be disposed on the second supporter SUP2. The ultrasonic application part UWV may generate an ultrasonic vibration. In an embodiment, for example, the ultrasonic vibration may have a frequency range from about 35 kilohertz (kHz) to about 172 kHz.

The mask MSK may be disposed between the upper bath U-BTH and the lower bath L-BTH. The first portion MS1 of the mask MSK may be disposed in the upper bath U-BTH and the lower bath L-BTH. The first pillars PL1 may be disposed under the frame portion BF of the mask MSK. The first pillars PL1 may support the frame portion BF.

The mask MSK may reciprocate along the first pillars PL1 in the third direction DR3. The first pillars PL1 facing each other in the first direction DR1 may reciprocate vertically in the third direction DR3. The frame portion BF of the mask MSK may be disposed on the first pillars PL1 and may reciprocate along the first pillars PL1 in the third direction DR3.

The fixing clamps CLP may be spaced apart from each other in the first direction DR1. The fixing clamps CLP may be respectively disposed on inner side surfaces of the second pillars PL2, which face each other in the first direction DR1. The fixing clamps CLP may be connected to the second pillars PL2. The second pillars PL2 may support the fixing clamps CLP. The fixing clamps CLP may be disposed on the frame portion BF of the mask MSK. The fixing clamps CLP may fix the frame portion BF of the mask MSK.

The moving part MOV may extend in the first direction DR1. The moving part MOV may be disposed between the second pillars PL2 spaced apart from each other in the first direction DR1. The rails RA may be disposed on the inner side surfaces of the second pillars PL2. In an embodiment, for example, the rails RA may extend further in the third direction DR3 than the second pillars PL2. The moving part MOV may be disposed on inner side surfaces of the rails RA, which face each other in the first direction DR1.

The moving part MOV may be coupled with the rails RA and may reciprocate along the rails RA in the third direction DR3.

The motor MO may provide a driving force to the moving part MOV. The motor MO may be disposed at an upper end of the rails RA. The moving part MOV may reciprocate along the rails RA in the third direction DR3 in response to the driving force provided from the motor MO.

The moving part MOV may be disposed on (or coupled to) the upper bath U-BTH and may move the upper bath U-BTH. The moving part MOV may reciprocate in the third direction DR3 to move the upper bath U-BTH back and forth in the third direction DR3.

The upper bath U-BTH may reciprocate in the third direction DR3 to form a sealed structure with the lower bath L-BTH. Due to the sealed structure, the first portion MS1 of the mask MSK may be enclosed between the upper bath U-BTH and the lower bath L-BTH. Contact portions U-CP of the upper bath U-BTH, which are portions of the upper bath U-BTH to contact the mask MSK, may be positioned on the second portion MS2 of the mask MSK. Contact portions L-CP of the lower bath L-BTH, which are portions of the lower bath L-BTH to contact the mask MSK, may be positioned under the second portion MS2 of the mask MSK. The contact portions U-CP of the upper bath U-BTH may overlap the contact portions L-CP of the lower bath L-BTH in the third direction DR3.

The deformation of the second portion MS2 may be reduced by the contact portions U-CP of the upper bath U-BTH and the contact portions L-CP of the lower bath L-BTH. In an embodiment, for example, the contact portions U-CP of the upper bath U-BTH and the contact portions L-CP of the lower bath L-BTH may include a material with an elasticity.

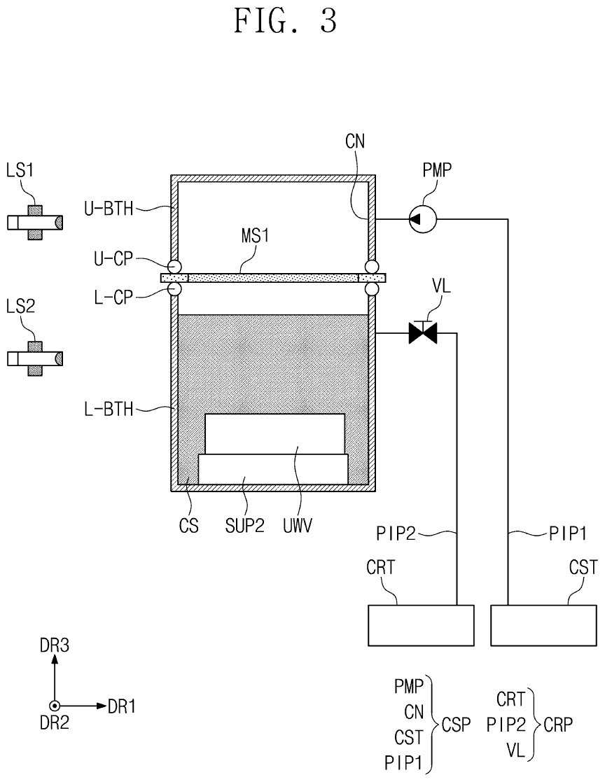

FIG. 3 is a view illustrating a detailed structure of a part A of FIG. 2. In FIG. 3, the same reference numerals denote the same elements as those in FIG. 2, and thus, any repetitive detailed descriptions of the same elements will be omitted.

Referring to FIG. 3, an embodiment of the mask cleaning device MCD may include a cleaning solution supply part CSP, a cleaning solution recovery part CRP, and first and second level sensors LS1 and LS2.

The cleaning solution supply part CSP may include a cleaning solution supply tank CST, a pump PMP, a first pipe PIP1, and a cleaning solution supply nozzle CN.

The cleaning solution supply tank CST may be connected to the upper bath U-BTH. The cleaning solution supply tank CST may accommodate the cleaning solution CS. The cleaning solution supply tank CST may be connected to the upper bath U-BTH through the first pipe PIP1 and may supply the cleaning solution CS to the upper bath U-BTH. The cleaning solution CS may be used to remove residual materials on the mask MSK after the deposition process of a display device. In an embodiment, for example, the cleaning solution CS may include dimethyl carbonate, however, the type of the cleaning solution CS according to embodiments of the present disclosure should not be limited to dimethyl carbonate.

The cleaning solution supply nozzle CN connected to the first pipe PIP1 may be disposed inside the upper bath U-BTH. The cleaning solution supply nozzle CN may spray the cleaning solution CS contained in the cleaning solution supply tank CST into the upper bath U-BTH.

The pump PMP may be connected to the first pipe PIP1 to supply pressure to the cleaning solution supply tank CST. The pump PMP may control the supply of the cleaning solution CS that is supplied from the cleaning solution supply tank CST to the upper bath U-BTH. Due to the pressure by the pump PMP, the cleaning solution CS contained in the cleaning solution supply tank CST may be supplied to the upper bath U-BTH via the first pipe PIP1 and the cleaning solution supply nozzle CN.

The first level sensor LS1 may be provided outside the upper bath U-BTH. The first level sensor LS1 may sense a first water level of the cleaning solution CS contained in the upper bath U-BTH. The first level sensor LS1 may control an operation of the pump PMP based on the sensed first water level. In an embodiment, for example, when the first level sensor LS1 detects that the first water level of the cleaning solution CS contained in the upper bath U-BTH exceeds a reference upper water level of the cleaning solution, the pump PMP may stop supplying the cleaning solution CS to the upper bath U-BTH. This will be described in detail later.

In an embodiment, as shown in FIG. 3, the first level sensor LS1 may be disposed outside the upper bath U-BTH, however, the present disclosure should not be limited thereto or thereby. According to another embodiment, the first level sensor LS1 may be disposed inside the upper bath U-BTH.

The cleaning solution recovery part CRP may include a cleaning solution recovery tank CRT, a second pipe PIP2, and a valve VL.

The cleaning solution recovery tank CRT may be connected to the lower bath L-BTH. The cleaning solution recovery tank CRT may be connected to the lower bath L-BTH by the second pipe PIP2 to recover the cleaning solution CS contained in the lower bath L-BTH. The second pipe PIP2 may be connected between the lower bath L-BTH and the cleaning solution recovery tank CRT.

The valve VL may connect the second pipe PIP2 and the lower bath L-BTH. The valve VL may be connected to the second pipe PIP2 to control the recovery of the cleaning solution CS to the cleaning solution recovery tank CRT. The valve VL may be opened or closed to control the recovery of the cleaning solution CS to the cleaning solution recovery tank CRT.

The second level sensor LS2 may be disposed outside the lower bath L-BTH. The second level sensor LS2 may detect a second water level of the cleaning solution CS contained in the lower bath L-BTH. The second level sensor LS2 may control the opening and closing of the valve VL based on the detected second water level. In an embodiment, for example, when the second level sensor LS2 detects that the second water level of the cleaning solution CS contained in the lower bath L-BTH is below a reference lower water level of the cleaning solution, the valve VL may be closed. This will be described in detail later.

In an embodiment, as shown in FIG. 3, the second level sensor LS2 may be disposed outside the lower bath L-BTH, however, the present disclosure should not be limited thereto or thereby. According to another embodiment, the second level sensor LS2 may be disposed inside the lower bath L-BTH.

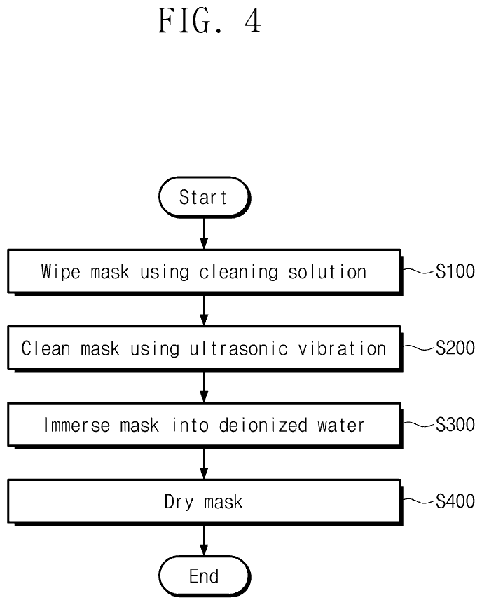

FIG. 4 is a flowchart illustrating a method of cleaning the mask (hereinafter, referred to as a mask cleaning method) according to an embodiment of the present disclosure.

Referring to FIGS. 2 and 4, an embodiment of the mask cleaning method using the mask cleaning device MCD may include wiping the mask MSK with the cleaning solution CS (S100), placing the mask between the upper bath U-BTH and the lower bath L-BTH to clean the mask MSK using the ultrasonic vibration (S200), immersing the cleaned mask MSK using the ultrasonic vibration into a deionized water (S300), and drying the immersed mask MSK (S400).

The mask including the first portion MS1 having the mesh shape, the second portion MS2 surrounding the first portion MS1, and the frame portion BF surrounding the second portion MS2 may be provided. After the deposition process of the display device using the mask MSK, materials may remain on the mask MSK. The residual materials may act as foreign substances in a subsequent deposition process. According to an embodiment of the present disclosure, the foreign substances may be removed by the mask cleaning device MCD.

The mask MSK may be wiped using a wiper soaked with the cleaning solution CS (S100). The residual foreign substances on the mask MSK may be partially removed. The wiping of the mask MSK using the cleaning solution CS (S100) may serve as a pretreatment process prior to removing the foreign substances using the mask cleaning device MCD. Accordingly, contamination of the cleaning solution CS contained in the upper bath U-BTH and the lower bath L-BTH may be reduced.

The wiped mask MSK may be disposed between the upper bath U-BTH and the lower bath L-BTH. The mask MSK may be fixed to the fixing clamp CLP and may reciprocate along the third direction DR3. The mask MSK may move in the third direction DR3 and then may be placed on the lower bath L-BTH. In an embodiment, for example, the first portion MS1 of the mask MSK may overlap the lower bath L-BTH.

The upper bath U-BTH may reciprocate along the third direction DR3 by the motor MO. The upper bath U-BTH may move in opposite direction of the third direction DR3 and then may form the sealed structure with the lower bath L-BTH. The upper bath U-BTH may overlap the first portion MS1 of the mask MSK. The first portion MS1 of the mask MSK may be sealed between the upper bath U-BTH and the lower bath L-BTH.

When the cleaning solution CS is supplied into the sealed space formed by the upper bath U-BTH and the lower bath L-BTH, the mask MSK may be cleaned using the ultrasonic cleaning process (S200). The cleaning solution CS used for the ultrasonic cleaning process may be recovered, and the upper bath U-BTH may move to separate the upper bath U-BTH from the lower bath L-BTH. This will be described in detail later.

The mask MSK cleaned using the ultrasonic vibration may be immersed into the deionized water (S300). The first portion MS1, the second portion MS2, and the frame portion BF of the mask MSK may be immersed into the deionized water contained in a bath The residual cleaning solution CS and materials on the mask MSK may be removed using the deionized water.

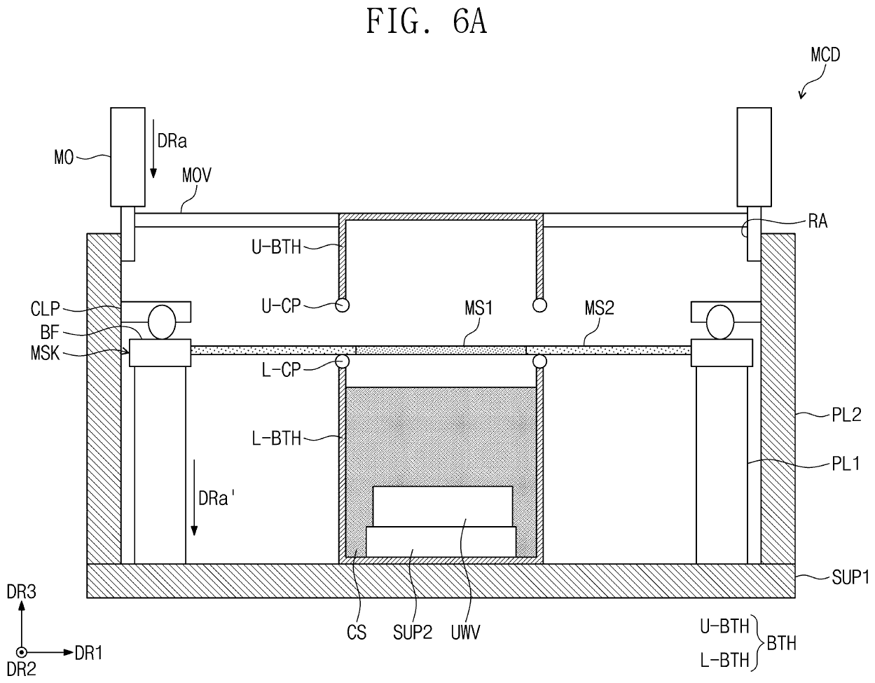

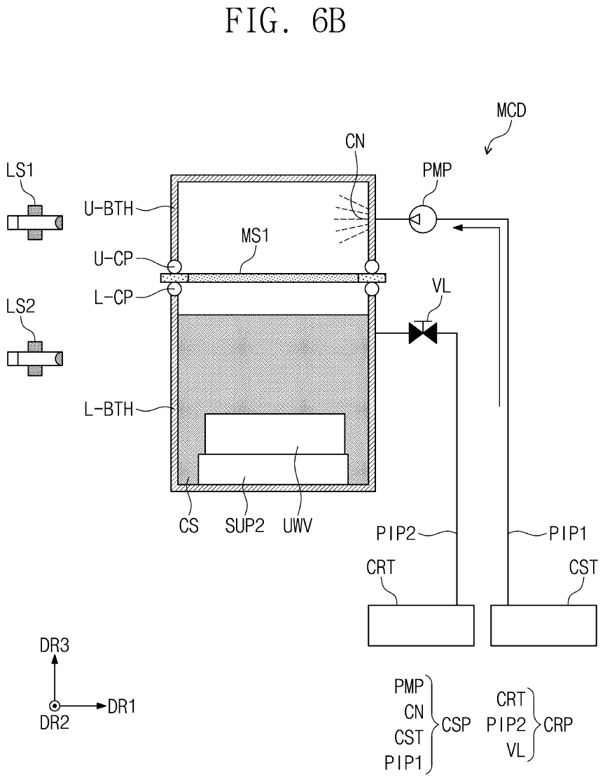

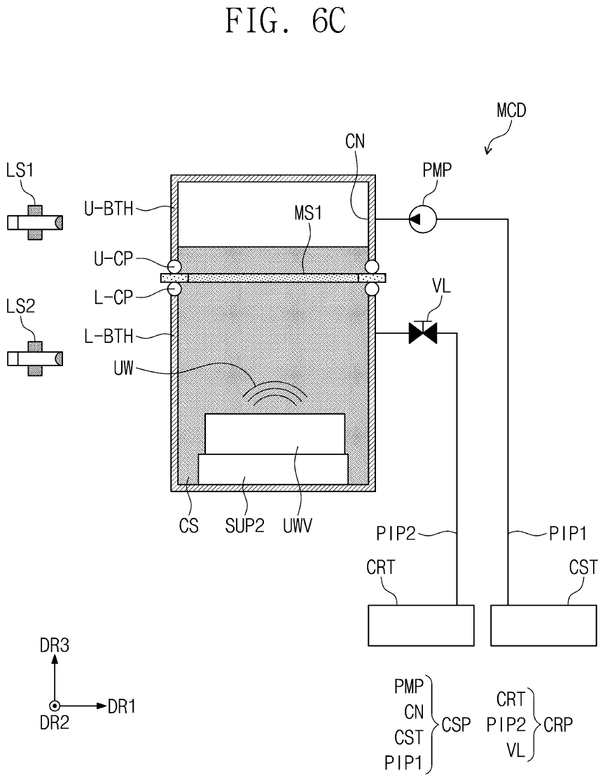

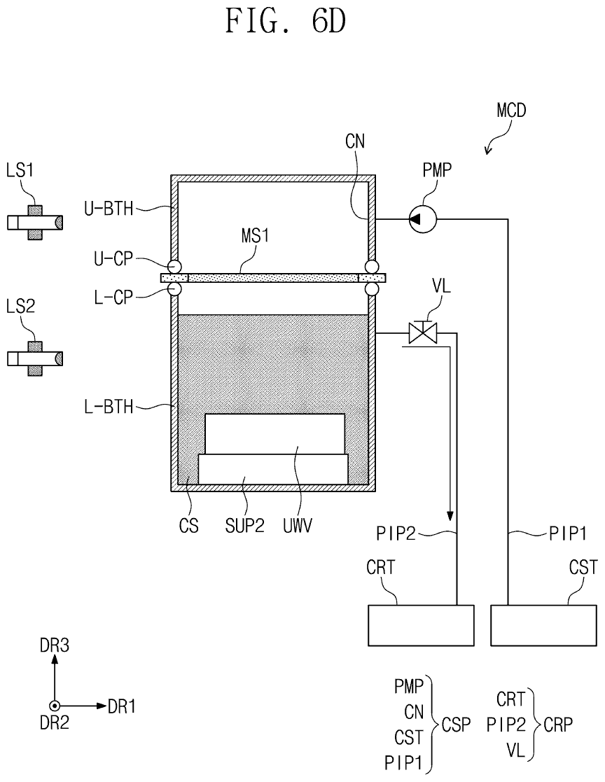

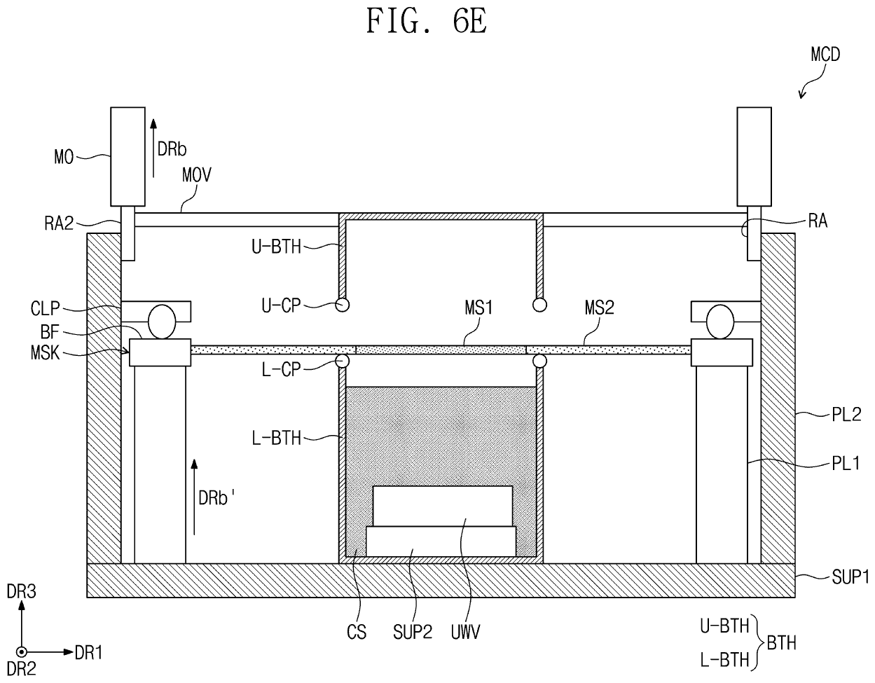

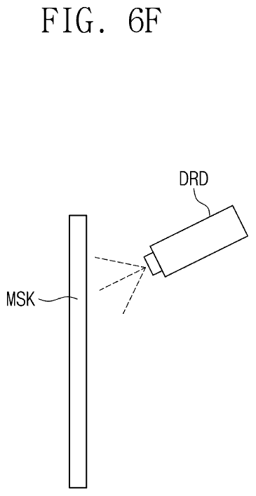

The immersed mask MSK may be removed from the deionized water bath. The mask MSK may be dried using a drying device DRD (refer to FIG. 6F) (S400). The drying device DRD may dry the mask MSK by vaporizing moisture remaining on the mask MSK. In an embodiment, for example, the drying device DRD may include an air gun.

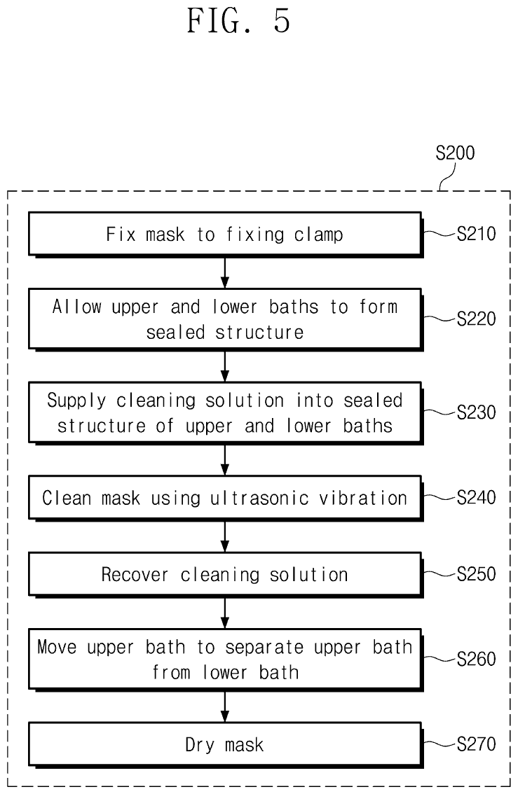

FIG. 5 is a flowchart illustrating an embodiment of the ultrasonic cleaning process shown in FIG. 4.

Referring to FIGS. 2 and 5, an embodiment of the ultrasonic cleaning process (S200) may include fixing the mask MSK to the fixing clamp CLP (S210), allowing the upper bath U-BTH and the lower bath L-BTH to form the sealed structure (S220), supplying the cleaning solution CS into the upper bath U-BTH and the lower bath L-BTH, which form the sealed structure (S230), cleaning the mask MSK using the ultrasonic vibration (S240), recovering the cleaning solution CS used in the process of cleaning the mask MSK (S250), moving the upper bath U-BTH to separate the upper bath U-BTH from the lower bath L-BTH (S260), and drying the mask MSK (S270).

The mask MSK may be disposed on the lower bath L-BTH. The mask MSK may be disposed on the first pillar PL1 that reciprocates along the third direction DR3. The mask MSK may reciprocate along the third direction DR3 by the first pillar PL1 and may be disposed on the lower bath L-BTH.

The mask MSK disposed above the lower bath L-BTH may be fixed to the fixing clamp CLP (S210). In an embodiment, for example, the frame portion BF of the mask MSK may be fixed to the fixing clamp CLP. The lower bath L-BTH may overlap the first portion MS1 of the mask MSK.

The upper bath U-BTH may be disposed on the mask MSK, and thus, the upper bath U-BTH and the lower bath L-BTH may form the sealed structure or define a sealed space therebetween (S220). The moving part MOV may be disposed on the upper bath U-BTH. The moving part MOV may receive the driving force from the motor MO and may reciprocate along the rails RA in the third direction DR3. The upper bath U-BTH may reciprocate along the third direction DR3 and may be disposed on the mask MSK. The upper bath U-BTH may overlap the first portion MS1 of the mask MSK.

The cleaning solution CS may be supplied into the sealed space formed by the upper bath U-BTH and the lower bath L-BTH (S220). The cleaning solution supply nozzle CN, which is connected to the cleaning solution supply tank CST, may be disposed in the upper bath U-BTH. The cleaning solution supply nozzle CN may be connected to the cleaning solution supply tank CST through the first pipe PIP1 and the pump PMP. The cleaning solution CS contained in the cleaning solution supply tank CST may be supplied to the upper bath U-BTH by the pressure from the pump PMP.

The cleaning solution CS may be supplied or may not be supplied into the upper bath U-BTH depending on the first water level detected by the first level sensor LS1. The first level sensor LS1 may be disposed outside the upper bath U-BTH. When it is determined that the first water level detected by the first level sensor LS1 exceeds the reference upper water level of the cleaning solution CS, the supply of the cleaning solution CS to the upper bath U-BTH may be stopped. In this case, the operation of the pump PMP may be halted, and thus, the supply of the cleaning solution CS to the upper bath U-BTH may be stopped.

When the operation of the pump PMP is stopped, the ultrasonic application part UWV may generate the ultrasonic vibration to clean the first portion MS1 of the mask MSK (S240).

After the ultrasonic cleaning process, the cleaning solution CS used in the process of cleaning the mask MSK using the ultrasonic vibration may be recovered to the cleaning solution recovery tank CRT. In an embodiment, for example, the valve VL connected between the lower bath L-BTH and the cleaning solution recovery tank CRT may be opened, and the cleaning solution CS contained in the lower bath L-BTH may be recovered to the cleaning solution recovery tank CRT. The second level sensor LS2 disposed outside the lower bath L-BTH may detect the second water level of the cleaning solution CS contained in the lower bath L-BTH. When the second water level of the cleaning solution CS contained in the lower bath L-BTH, which is detected by the second level sensor LS2, is below the reference lower water level of the cleaning solution CS, the valve VL may be closed. When the valve VL is closed, the recovery of the cleaning solution CS to the cleaning solution recovery tank CRT from the lower bath L-BTH through the second pipe PIP2 may be stopped.

The upper bath U-BTH may move in the third direction DR3, and thus, the upper bath U-BTH may be separated from the lower bath L-BTH (S260).

The separated mask MSK may be dried using the drying device DRD (S270). The residual cleaning solution CS on the mask MSK may be vaporized through the drying of the mask (S270).

FIGS. 6A to 6F are views illustrating an embodiment of an operation of the mask cleaning device.

Referring to FIG. 6A, in an embodiment, the mask MSK may be disposed on the lower bath L-BTH and may be fixed by the fixing clamp CLP. The mask MSK may be disposed on the lower bath L-BTH by the first pillar PL1 that reciprocates along the third direction DR3. In an embodiment, for example, the first pillar PL1 may move in a downward direction DRa′ parallel to the third direction DR3. The first portion MS1 of the mask MSK may overlap the lower bath L-BTH, and the frame portion BF of the mask MSK may be disposed on the first pillar PL1 and may be fixed by the fixing clamp CLP.

The upper bath U-BTH may reciprocate along the third direction DR3 by the operation of the motor MO and may be disposed on the mask MSK. The upper bath U-BTH may be coupled with the moving part MOV. The moving part MOV may be coupled with the rails RA and may move along the rails RA. In an embodiment, for example, the moving part MOV may move in a downward direction DRa parallel to the third direction DR3.

In FIG. 6A, the downward direction DRa and the downward direction DRa′ are illustrated as a same direction, however, the present disclosure should not be limited thereto or thereby. The upper bath U-BTH and the lower bath L-BTH may form the sealed structure. The first portion MS1 of the mask MSK may be disposed in the sealed space formed by the upper bath U-BTH and the lower bath L-BTH. The mask cleaning device MCD may perform the cleaning process only on the first portion MS1 of the mask MSK.

In a case where the entire mask MSK is immersed in the cleaning solution CS in the process of cleaning the mask MSK, the amount of the cleaning solution CS used increases, and the waste amount of the cleaning solution CS after the cleaning process increases. According to an embodiment of the present disclosure, only the first portion MS1 of the mask MSK may be cleaned by the mask cleaning device MCD. Residual materials attached to the openings defined by a mesh structure of the first portion MS1 may be easily removed through the ultrasonic cleaning process. The mask cleaning method according to an embodiment of the present disclosure may reduce the amount of the cleaning solution CS used. Accordingly, the waste amount of the cleaning solution CS may be reduced. Thus, the reliability of the cleaning process by the mask cleaning device MCD and the mask cleaning method may be improved.

Referring to FIG. 6B, the cleaning solution supply tank CST may supply the cleaning solution CS to the upper bath U-BTH through the first pipe PIP1 and the cleaning solution supply nozzle CN. The cleaning solution CS may be contained in the upper bath U-BTH and the lower bath L-BTH due to the sealed structure formed by the upper bath U-BTH and the lower bath L-BTH. The operation of the pump PMP may be controlled depending on the first water level of the cleaning solution CS contained in the upper bath U-BTH, which is detected by the first level sensor LS1 disposed outside the upper bath U-BTH. The pressure applied to the cleaning solution supply tank CST from the pump PMP may be controlled by the first water level detected by the first level sensor LS1.

Referring to FIG. 6C, when the first water level of the cleaning solution CS increases to the water level detected by the first level sensor LS1, the pump PMP may be stopped. That is, the pump PMP may stop supplying the cleaning solution CS to the upper bath U-BTH. When the pump PMP is stopped, the cleaning solution CS may not be supplied to the upper bath U-BTH.

The first level sensor LS1 may be disposed parallel to the upper bath U-BTH (or overlap the upper bath U-BTH horizontally, i.e., in the first direction DR1 or the second direction DR2). The cleaning solution CS may be supplied until the water level reaches the first water level detected by the first level sensor LS1. When the cleaning solution CS is supplied to reach the first water level, the first portion MS1 of the mask MSK may be completely immersed in the cleaning solution CS.

The ultrasonic application part UWV disposed in the lower bath L-BTH may generate the ultrasonic vibration UW. The cleaning solution CS may vibrate by the ultrasonic vibration UW and may clean the first portion MS1 of the mask MSK. The ultrasonic vibration UW may have a frequency range from about 35 kHz to about 172 kHz. In an embodiment, for example, the ultrasonic application part UWV may generate the ultrasonic vibration UW of about 35 kHz, about 72 kHz, about 100 kHz, or about 172 kHz or may generate the ultrasonic vibration UW with mixed frequencies.

According to an embodiment of the present disclosure, the mask cleaning device MCD may perform the cleaning process on the mask MSK using the ultrasonic application part UWV. The ultrasonic application part UWV may generate the ultrasonic vibration UW at a frequency of about 35 kHz for a duration of about 120 seconds. When the ultrasonic vibration UW is generated for a duration of about 120 seconds, the first portion having the mesh structure may not be damaged. Since the cleaning process using the ultrasonic vibration UW is not a direct contact cleaning process, damages to the first portion MS1 of the mask MSK may be reduced. In addition, since operators do not manually clean the mask MSK using a wiper soaked with the cleaning solution CS, human errors may be effectively prevented from occurring. Accordingly, the lifespan of the mask MSK may be improved, and the replacement cycle of the mask MSK may increase. Therefore, the reliability of the mask cleaning device MCD and the mask cleaning method using the mask cleaning device MCD may be improved.

According to an embodiment of the present disclosure, the mask cleaning device MCD may perform the cleaning process on the mask MSK using the ultrasonic application part UWV. The ultrasonic application part UWV may uniformly apply the ultrasonic vibration UW to the entire surface of the first portion MS1. Cleaning uniformity for the first portion MS1 of the mask MSK may be enhanced. As a result, the cleaning quality of the mask cleaning method may be improved.

In addition, according to an embodiment of the present disclosure, the second portion MS2 and the frame portion BF of the mask MSK may not be cleaned by the mask cleaning device MCD. The second portion MS2 and the frame portion BF of the mask MSK may not be in contact with the cleaning solution CS. The ultrasonic vibration UW may not be applied to the second portion MS2 and the frame portion BF of the mask MSK. Accordingly, the damage to the area between the edge portion of the second portion MS2 and the frame portion BF, which is bonded and then tapped, may be reduced. Thus, a tensile force of the second portion MS2 surrounding the first portion MS1 may be effectively prevented from weakening. The phenomenon in which the mesh structure of the first portion MS1 is separated due to the weakened tensile force may be effectively prevented or substantially eliminated. Accordingly, the reliability of the mask cleaning device MCD and the mask cleaning method using the mask cleaning device MCD may be improved.

Referring to FIG. 6D, the cleaning solution recovery tank CRT may recover the cleaning solution CS from the lower bath L-BTH after the mask cleaning process. The valve VL connected to the cleaning solution recovery tank CRT and the lower bath L-BTH may be opened, and thus, the cleaning solution CS contained in the lower bath L-BTH may be recovered to the cleaning solution recovery tank CRT.

The mask cleaning device MCD according to an embodiment of the present disclosure may further include a filter connected between the cleaning solution recovery tank CRT and the cleaning solution supply tank CST. The filter may filter the recovered cleaning solution CS to allow the cleaning solution CS to be reused through the cleaning solution supply tank CST.

The operation of the valve VL may be controlled depending on the second water level of the cleaning solution CS contained in the lower bath L-BTH, which is detected by the second level sensor LS2 outside the lower bath L-BTH. The valve VL may be opened or closed by the second level sensor LS2.

The second level sensor LS2 may be disposed parallel to the lower bath L-BTH (or overlap the lower bath L-BTH horizontally, i.e., in the first direction DR1 or the second direction DR2). The cleaning solution CS may be discharged until the water level of the cleaning solution CS reaches the second water level detected by the second level sensor LS2. Since the cleaning solution CS is discharged to the second water level, the cleaning solution CS may not overflow when the upper bath U-BTH is separated from the lower bath L-BTH.

Referring to FIG. 6E, the upper bath U-BTH may move in an upward direction DRb by the motor MO. In an embodiment, for example, the upward direction DRb may be substantially parallel to the third direction DR3. The upper bath U-BTH may be separated from the lower bath L-BTH.

The mask MSK may be separated from the fixing clamp CLP fixing the frame portion BF of the mask MSK. The first pillar PL1 may move in an upward direction DRb′. The mask MSK may be separated from the lower bath L-BTH.

In FIG. 6E, the upward direction DRb and the upward direction DRb′ are illustrated as a same direction, however, the present disclosure should not be limited thereto or thereby.

Referring to FIG. 6F, the separated mask MSK may be dried by the drying device DRD. The drying device DRD may vaporize the residual cleaning solution on the mask MSK.

The invention should not be construed as being limited to the embodiments set forth herein. Rather, these embodiments are provided so that this disclosure will be thorough and complete and will fully convey the concept of the invention to those skilled in the art.

While the invention has been particularly shown and described with reference to embodiments thereof, it will be understood by those of ordinary skill in the art that various changes in form and details may be made therein without departing from the spirit or scope of the invention as defined by the following claims.

What is claimed is:

1. A mask cleaning device comprising:
a bath part comprising an upper bath and a lower bath spaced apart from the upper bath, wherein the bath part allows a mask to be placed between the upper bath and the lower bath;
a cleaning solution supply part connected to the bath part to supply a cleaning solution to the bath part;
an ultrasonic application part disposed in the bath part to generate an ultrasonic vibration; and
a cleaning solution recovery part connected to the bath part to recover the cleaning solution.

2. The mask cleaning device of claim 1, wherein the mask comprises:
a first portion having a mesh shape;
a second portion surrounding the first portion and tensioning the first portion; and
a frame portion surrounding the second portion.

3. The mask cleaning device of claim 2, wherein the first portion has a thickness in a range of about 50 micrometers to about 60 micrometers.

4. The mask cleaning device of claim 2, wherein when the mask is disposed between the upper bath and the lower bath, the first portion is disposed between the upper bath and the lower bath.

5. The mask cleaning device of claim 2, further comprising:
a first pillar which is disposed under the frame portion and supports the frame portion;
a fixing clamp which fixes the frame portion thereto; and
a second pillar which is connected to the fixing clamp and supports the fixing clamp.

6. The mask cleaning device of claim 5, further comprising:
a moving part which is disposed on the upper bath and moves the upper bath;
a motor which provides a driving force to the moving part; and
a rail connected to the second pillar, wherein the moving part moves along the rail.

7. The mask cleaning device of claim 2, wherein the cleaning solution supply part comprises:
a cleaning solution supply tank which supplies the cleaning solution to the upper bath;
a first pipe connected between the upper bath and the cleaning solution supply tank; and
a cleaning solution supply nozzle disposed in the upper bath and connected to the first pipe.

8. The mask cleaning device of claim 7, wherein the cleaning solution supply part further comprises a pump which controls a supply of the cleaning solution to the upper bath from the cleaning solution supply tank.

9. The mask cleaning device of claim 8, further comprising:
a first level sensor disposed outside the upper bath to detect a first water level of the cleaning solution contained in the upper bath.

10. The mask cleaning device of claim 9, wherein, when the first water level of the cleaning solution contained in the upper bath, which is detected by the first level sensor, exceeds a reference upper water level of the cleaning solution, the pump stops the supply of the cleaning solution to the upper bath.

11. The mask cleaning device of claim 10, wherein, after the pump stops the supply of the cleaning solution to the upper bath, the ultrasonic application part generates the ultrasonic vibration to clean the first portion.

12. The mask cleaning device of claim 11, wherein the ultrasonic vibration has a frequency in a range from about 35 kHz to about 172 kHz.

13. The mask cleaning device of claim 1, wherein the cleaning solution recovery part comprises:
a cleaning solution recovery tank which recovers the cleaning solution from the lower bath; and
a second pipe connected between the lower bath and the cleaning solution recovery tank.

14. The mask cleaning device of claim 13, wherein the cleaning solution recovery part further comprises a valve which controls a recovery of the cleaning solution to the cleaning solution recovery tank from the lower bath.

15. The mask cleaning device of claim 14, further comprising:
a second level sensor disposed outside the lower bath to detect a second water level of the cleaning solution contained in the lower bath.

16. The mask cleaning device of claim 15, wherein, when the second water level of the cleaning solution contained in the lower bath, which is detected by the second level sensor, is below a reference lower water level of the cleaning solution, the valve is closed to stop the recovery of the cleaning solution to the cleaning solution recovery tank from the lower bath.

17. A method of cleaning a mask, the method comprising:
fixing the mask to a fixing clamp to place the mask on a lower bath;
placing an upper bath on the mask to overlap the lower bath to allow the upper bath and the lower bath to form a sealed space therebetween;
supplying a cleaning solution into the sealed spaced between the upper and lower baths;
performing an ultrasonic cleaning on the mask;
recovering the cleaning solution used in the ultrasonic cleaning of the mask; and
moving the upper bath to separate the upper bath from the lower bath.

18. The method of claim 17, wherein the mask comprises:
a first portion having a mesh shape;
a second portion surrounding the first portion and tensioning the first portion; and
a frame portion surrounding the second portion.

19. The method of claim 18, wherein the placing the mask on the lower bath to overlap the lower bath comprises placing the first portion between the upper bath and the lower bath.

20. The method of claim 19, wherein the supplying the cleaning solution comprises operating a pump connected between the upper bath and a cleaning solution supply tank to supply the cleaning solution contained in the cleaning solution supply tank to the upper bath.
